(19) United States
(12) Patent Application Publication
(10) Pub. No.: US 2021/0391399 A1
(43) Pub. Date: Dec. 16, 2021

(54) ARRAY SUBSTRATE AND DISPLAY PANEL

(71) Applicant: Wuhan China Star Optoelectronics Semiconductor Display Technology Co., Ltd., Wuhan (CN)

(72) Inventor: Jinrong ZHAO, Wuhan (CN)

(73) Assignee: Wuhan China Star Optoelectronics Semiconductor Display Technology Co., Ltd., Wuhan (CN)

(21) Appl. No.: 16/641,239

(22) PCT Filed: Dec. 17, 2019
(86) PCT No.: PCT/CN2019/126065

§ 371 Date: Feb. 23, 2020

(30) Foreign Application Priority Data
Oct. 22, 2019 (CN) 201911007975.6

(51) Int. Cl. H01L 27/32

(52) U.S. Cl. CPC H01L 27/3258; H01L 51/0097

(57) ABSTRACT

An array substrate and a display panel are provided. The array substrate includes a flexible substrate, a buffer layer, a semiconductor layer, a first gate insulating layer, a first gate, an intermediate dielectric layer, an organic filling layer, a plurality of sources, and a plurality of drains sequentially disposed. The array substrate further includes a hydrophilicity-hydrophobicity matching layer disposed among the organic filling layer and the sources and drains.

### FIELD OF INVENTION

The present invention relates to the field of display technologies, and particularly to an array substrate and a display panel.

### BACKGROUND OF INVENTION

With active-matrix organic light emitting diode (AMOLED) display panel technology becoming more mature in the industry, successful mass production of flexible organic light emitting diode (OLED) display panels is not only beneficial to a manufacturing of new generation high-end smart phones, but also has a profound impact on an application of wearable devices due to flexible OLED display panels' low power consumption and bendable characteristics. In the future, flexible OLED display panels will be widely used with a continuous penetration of personal smart terminals. Compared with traditional display panels, flexible OLED display panels have obvious advantages. They are not only lightweight and thin in size, but also lower in power consumption than conventional devices, which is beneficial in improving an endurance of the devices, and also reduces a probability of accidental equipment damage due to their characteristics of bendability and good flexibility.

Conventional OLED display panels include an OLED device and a thin film transistor (TFT) array substrate. FIG. 1 is a schematic structural diagram of a conventional flexible OLED display panel. The TFT array structure includes a flexible substrate 10, a barrier layer 20, a buffer layer 30, a first gate insulating layer 40, a semiconductor layer 35 interposed between the first gate insulating layer 40 and the buffer layer 30, a first gate 45 disposed on the first gate insulating layer 40, a second gate insulating layer 50 covering the first gate 45, a second gate 55 disposed on the second gate insulating layer 50, an intermediate dielectric layer 60 covering the second gate 55, an organic filling layer 70 disposed on the intermediate dielectric layer 60 and filling in all plurality of through holes 110 in a display region and at least one through hole 120 in a non-display region, a plurality of sources and a plurality of drains disposed on the organic filling layer 70 and electrically connected to both ends of the semiconductor layer 35 through through holes 130 and 140, respectively, and a planarization layer 80 covering the sources, the drains, the organic filling layer 70, and a top of the at least one through hole 120, which are sequentially disposed from bottom to top. Subsequently, an anode of the OLED device is disposed on the planarization layer 80, after that, a pixel definition layer 90 and other structures of the OLED device are disposed thereon.

After the planarization layer process is performed in the conventional structure, a large area of the planarization layer peels off, which affects the yield, and therefore becomes an urgent problem.

### Technical Problem

After the planarization layer process is performed in the conventional structure, a large area of the planarization layer peels off, which affects the yield, and therefore becomes an urgent problem.

### SUMMARY OF INVENTION

### Technical Solutions

In order to solve the above-mentioned problems in the conventional art, an object of the present invention is to provide an array substrate, by adding a hydrophilicity-hydrophobicity matching layer among an organic filling layer and a source and a drain, the occurrence of fluorine-carbon bonds between the organic filling layer and the planarization layer is avoided, thereby improving the phenomenon of planarization layer peeling. In addition, the arrangement of the hydrophilicity-hydrophobicity matching layer of the present invention does not increase the number of photomasks, which can effectively improve the yield and reduce the manufacturing cost of the product.

To achieve the above object, the present invention provides an array substrate including a flexible substrate, a buffer layer, a semiconductor layer, a first gate insulating layer, a first gate, an intermediate dielectric layer, an organic filling layer, a plurality of sources, and a plurality of drains sequentially disposed, the array substrate further including a hydrophilicity-hydrophobicity matching layer disposed among the organic filling layer, the sources, and the drains.

In one embodiment of the present invention, the hydrophilicity-hydrophobicity matching layer consists of an inorganic material.

In one embodiment of the present invention, the hydrophilicity-hydrophobicity matching layer is a silicon oxide layer, a silicon nitride layer, or a composite layer of silicon oxide and silicon nitride.

In one embodiment of the present invention, the hydrophilicity-hydrophobicity matching layer is disposed on the organic filling layer and covers the sources and the drains.

In one embodiment of the present invention, the array substrate further including a planarization layer disposed on the hydrophilicity-hydrophobicity matching layer and covering the sources and the drains.

In one embodiment of the present invention, the array substrate further including a second gate insulating layer disposed between the first gate insulating layer and the intermediate dielectric layer, and a second gate disposed between the second gate insulating layer and the intermediate dielectric layer.

The present invention further provides an array substrate including a flexible substrate, a buffer layer, a semiconductor layer, a first gate insulating layer, a first gate, an intermediate di electric layer, an organic filling layer, a plurality of sources, and a plurality of drains sequentially disposed, wherein the array substrate further includes a hydrophilicity-hydrophobicity matching layer disposed on the organic filling layer.

In one embodiment of the present invention, the hydrophilicity-hydrophobicity matching layer consists of an inorganic material.

In one embodiment of the present invention, the hydrophilicity-hydrophobicity matching layer is a silicon oxide layer, a silicon nitride layer, or a composite layer of silicon oxide and silicon nitride.

In one embodiment of the present invention, the hydrophilicity-hydrophobicity matching layer is disposed on the organic filling layer and covers the sources and the drains.

In one embodiment of the present invention, the array substrate further including a planarization layer disposed on the hydrophilicity-hydrophobicity matching layer and covering the sources and the drains.

In one embodiment of the present invention, the array substrate further including a second gate insulating layer disposed between the first gate insulating layer and the intermediate dielectric layer, and a second gate disposed between the second gate insulating layer and the intermediate dielectric layer.

In one embodiment of the present invention, the array substrate further including a second gate insulating layer disposed between the first gate insulating layer and the intermediate dielectric layer, and a second gate disposed between the second gate insulating layer and the intermediate dielectric layer.

In order to achieve the above object, the present invention further provides a display panel, including: an array substrate including a flexible substrate, a buffer layer, a semiconductor layer, a first gate insulating layer, a first gate, an intermediate dielectric layer, an organic filling layer, a plurality of sources, and a plurality of drains sequentially disposed; a first electrode layer disposed on the array substrate; a pixel definition layer disposed on the array substrate and partially covering the first electrode layer; a luminous layer disposed on the first electrode layer; and a second electrode layer disposed on the luminous layer, wherein the display panel further includes: a hydrophilicity-hydrophobicity matching layer disposed among the organic filling layer, the sources, and the drains.

In one embodiment of the present invention, the display panel further including a planarization layer disposed on the hydrophilicity-hydrophobicity matching layer and covering the sources and the drains.

In one embodiment of the present invention, the hydrophilicity-hydrophobicity matching layer consists of an inorganic material.

In one embodiment of the present invention, the hydrophilicity-hydrophobicity matching layer is a silicon oxide layer, a silicon nitride layer, or a composite layer of silicon oxide and silicon nitride.

In one embodiment of the present invention, the hydrophilicity-hydrophobicity matching layer is disposed among the organic filling layer, the first electrode layer, and part of the pixel definition layer.

In one embodiment of the present invention, the array substrate further includes a second gate insulating layer disposed between the first gate insulating layer and the intermediate dielectric layer, and a second gate disposed between the second gate insulating layer and the intermediate dielectric layer.

### Beneficial Effect

Through the arrangement of the hydrophilicity-hydrophobicity matching layer of the present invention, a hydrophilicity-hydrophobicity matching layer is added among the organic filling layer, the sources, and the drains. Since the hydrophilicity-hydrophobicity matching layer is made of an inorganic material, its matching ability of hydrophilicity and hydrophobicity can prevent the organic filling layer and the planarization layer from the occurrence of fluorine-carbon bond (C—F), thereby reducing the phenomenon of the planarization layer peeling off.

### BRIEF DESCRIPTION OF FIGURES

In order to illustrate the technical solutions of the present disclosure or the related art in a clearer manner, the drawings desired for the present disclosure or the related art will be described hereinafter briefly. Obviously, the following drawings merely relate to some embodiments of the present disclosure, and based on these drawings, a person skilled in the art may obtain the other drawings without any creative effort.

FIG. 1 shows a schematic structural diagram of a conventional flexible display panel.

FIG. 2 is a schematic structural diagram of a flexible display panel according to an embodiment provided by the present invention.

FIG. 3 is a schematic structural diagram of a flexible display panel according to another embodiment provided by the present invention.

### DETAILED DESCRIPTION OF EMBODIMENTS

The following description of each embodiment, with reference to the accompanying drawings, is used to exemplify specific embodiments which may be carried out in the present invention. Directional terms mentioned in the present invention, such as “top”, “bottom”, “front”, “back”, “left”, “right”, “inside”, “outside”, “side”, etc., are only used with reference to the orientation of the accompanying drawings. Therefore, the used directional terms are intended to illustrate, but not to limit, the present invention. In the drawings, components having similar structures are denoted by the same numerals.

In addition, in order to avoid obscuring the invention due to unnecessary details, only the structures and/or processing steps that are closely related to the solution according to the invention are shown in the drawings.

The invention provides an array substrate, which includes a flexible substrate, a buffer layer, a semiconductor layer, a first gate insulating layer, a first gate, an intermediate dielectric layer, an organic filling layer, and a plurality of sources and a plurality of drains sequentially disposed. The array substrate further includes a hydrophilicity-hydrophobicity matching layer disposed among the organic filling layer and the sources and drains.

Through the arrangement of the hydrophilicity-hydrophobicity matching layer of the present invention, a hydrophilicity-hydrophobicity matching layer is added among the organic filling layer, the sources, and the drains. For example, the hydrophilicity-hydrophobicity matching layer is disposed on the organic filling layer and covers the sources and the drains. Alternatively, the hydrophilicity-hydrophobicity matching layer is disposed on the organic filling layer, and further includes a planarization layer disposed on the hydrophilicity-hydrophobicity matching layer, and covers the sources and the drains. Because the hydrophilicity-hydrophobicity matching layer is made of an inorganic material, its matching ability of hydrophilicity and hydrophobicity can prevent the organic filling layer and the planarization layer from the occurrence of fluorine-carbon bond (C—F), thereby reducing the phenomenon of the planarization layer peeling off. The details are as follows.

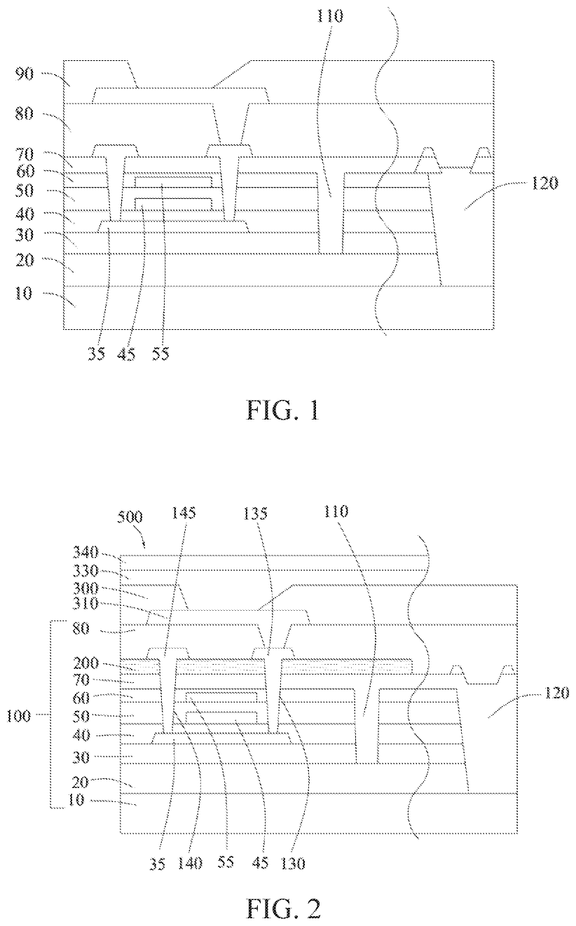

Please refer to FIG. 2, which shows a schematic structural diagram of a display panel according to an embodiment provided by the present invention. The display panel 500 includes an organic light emitting diode (OLED) device and a thin film transistor (TFT) array substrate 100. The TFT array substrate 100 includes a flexible substrate 10, a barrier layer 20 disposed on the flexible substrate 10, a buffer layer 30, a first gate insulating layer 40, a semiconductor layer 35 disposed between the first gate insulating layer 40 and the buffer layer 30, a first gate 45 disposed on the first gate insulating layer 40, a second gate insulating layer 50 covering the first gate 45, a second gate 55 disposed on the second gate insulating layer 50, an intermediate dielectric layer 60 covering the second gate 55, an organic filling layer 70 disposed on the intermediate dielectric layer 60, and a hydrophilicity-hydrophobicity matching layer 200 disposed on the organic filling layer 70. Subsequently, a plurality of sources 135 and a plurality of drains 145 are disposed on the hydrophilicity-hydrophobicity matching layer 200, and are electrically connected to both ends of the semiconductor layer 35 through through holes 130 and 140, respectively. Meanwhile, the organic filling layer 70 fills at least one through hole 110 in a display region and at least one through hole 120 in a non-display region.

Next, a planarization layer 80 is disposed on the TFT array substrate 100 to cover a top of the hydrophilicity-hydrophobicity matching layer 200, the sources 135, the drains 145, a portion of the organic filling layer 70, and a top of the at least one through hole 120. Then, a first electrode layer 310 is disposed on the planarization layer 80, a pixel definition layer 320 is disposed on the TFT array substrate 100 and covers a portion of the first electrode layer 310, a luminous layer 330 is disposed on the first electrode layer 310, and a second electrode layer 340 is disposed on the luminous layer 330.

The hydrophilicity-hydrophobicity matching layer 200 consists of an inorganic material, such as a silicon oxide layer, a silicon nitride layer, or a composite layer of silicon oxide and silicon nitride. A method for forming the hydrophilicity-hydrophobicity matching layer 200 is, for example, a low temperature chemical vapor deposition (CVD) process, and a processing temperature ranges from 220° C. to 240° C.

The organic filling layer 70 has an organic photoresist component, and a benzene ring in a molecular formula of the organic photoresist originally forms a hydrocarbon bond (C—H) with a hydrogen atom. However, in a manufacturing process of the TFT array, after dry etching of the sources is completed, a fluorine atom having strong electronegativity replaces the hydrogen atom to form a carbon-fluorine bond, and electrons are tightly adsorbed around the fluorine atom nucleus, which greatly reduces surface free energy of the organic filling layer 70. According to a formula of a hydrophilicity index of solid surface, when the index is less than 5 mJ^{1/2}/m, the solid surface appears to be hydrophobic, and when the index is greater than or close to 5 mJ^{1/2}m, the solid surface appears to be hydrophilic. It can be known that reducing the surface free energy will enhance the hydrophilicity. Carbon-fluorine bonds are formed on a surface of the organic filling layer 70, which is hydrophobic, but a wet film of the planarization layer 80 contains a hydroxyl group (COOH), and the hydroxyl group tends to be hydrophilic. Therefore, the hydrophilicity-hydrophobicity properties of the organic filling layer 70 and the planarization layer 80 do not match, resulting in poor adhesion between the organic filling layer 70 and the planarization layer 80, and the planarization layer 80 easily peeling off.

Through the arrangement of the hydrophilicity-hydrophobicity matching layer 200 in the embodiment of the present invention, the hydrophilicity-hydrophobicity matching layer 200 is added among the organic filling layer 70, the sources 135, and the drains 145. Since the hydrophilicity-hydrophobicity matching layer 200 is made of the inorganic material, its matching ability of hydrophilicity and hydrophobicity can prevent the organic filling layer 70 and the planarization layer 80 from the occurrence of fluorine-carbon bond (C—F), thereby reducing the phenomenon of the planarization layer 80 peeling off.

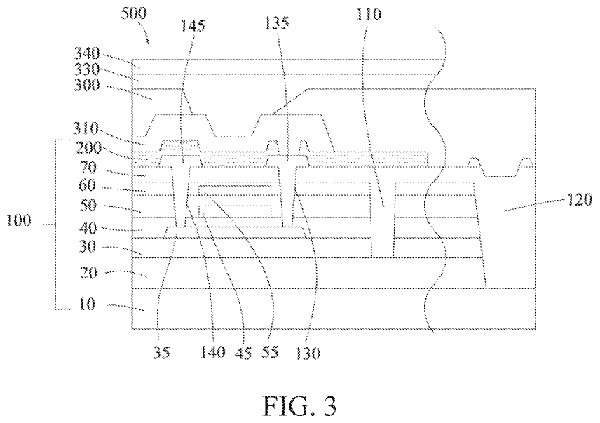

Furthermore, the present invention further provides another embodiment. Please refer to FIG. 3, which shows a schematic structural diagram of a display panel according to another embodiment provided by the present invention. Some structures and component numbers are same as those in the embodiment of FIG. 2 and will not be repeated here. Only the differences will be described.

In the present embodiment, the planarization layer 80 provided above the organic filling layer 70, the sources 135, and the drains 145 is directly replaced with the hydrophilicity-hydrophobicity matching layer 200; that is, after the organic filling layer 70, the sources 135, and drains 145 are disposed, the hydrophilicity-hydrophobicity matching layer 200 is then disposed to cover the organic filling layer 70, the sources 135, and the drains 145, and then the first electrode layer 310, the pixel definition layer 320, the luminous layer 330, and the second electrode layer 340 are disposed.

Understandably, referring to the embodiments provided above, where the first and second electrode layers are used, if the first electrode layer is an anode, the second electrode layer is a cathode; if the first electrode layer is a cathode, the second electrode layer is an anode.

Optionally, the first electrode layer can be a multi-layer composite film, and the multi-layer composite film includes a top indium tin oxide film, a silver film, and a bottom indium tin oxide film disposed in this order.

Optionally, a hole injection layer, a hole transport layer, an electron injection layer, and an electron transport layer can be further included between the first electrode layer and the second electrode layer.

The abovementioned display panel can further include an encapsulation cover, a filled inert gas, and the like, which are not repeated here.

Embodiments of the present invention have been described, but not intended to impose any unduly constraint to the appended claims. For a person skilled in the art, any modification of equivalent structure or equivalent process made according to the disclosure and drawings of the present invention, or any application thereof, directly or indirectly, to other related fields of technique, is considered encompassed in the scope of protection defined by the claims of the present invention.

What is claimed is:

1. An array substrate, comprising a flexible substrate, a buffer layer, a semiconductor layer, a first gate insulating layer, a first gate, an intermediate dielectric layer, an organic filling layer, a plurality of sources, and a plurality of drains sequentially disposed, the array substrate further comprising:
a hydrophilicity-hydrophobicity matching layer disposed among the organic filling layer, the sources, and the drains.

2. The array substrate according to claim 1, wherein the hydrophilicity-hydrophobicity matching layer consists of an inorganic material.

3. The array substrate according to claim 2, wherein the hydrophilicity-hydrophobicity matching layer is a silicon oxide layer, a silicon nitride layer, or a composite layer of silicon oxide and silicon nitride.

4. The array substrate according to claim 3, wherein the hydrophilicity-hydrophobicity matching layer is disposed on the organic filling layer and covers the sources and the drains.

5. The array substrate according to claim 1, further comprising a planarization layer disposed on the hydrophilicity-hydrophobicity matching layer and covering the sources and the drains.

6. The array substrate according to claim 1, further comprising a second gate insulating layer disposed between the first gate insulating layer and the intermediate dielectric layer, and a second gate disposed between the second gate insulating layer and the intermediate dielectric layer.

7. An array substrate, comprising a flexible substrate, a buffer layer, a semiconductor layer, a first gate insulating layer, a first gate, an intermediate dielectric layer, an organic filling layer, a plurality of sources, and a plurality of drains sequentially disposed, wherein the array substrate further comprises a hydrophilicity-hydrophobicity matching layer disposed on the organic filling layer.

8. The array substrate according to claim 7, wherein the hydrophilicity-hydrophobicity matching layer consists of an inorganic material.

9. The array substrate according to claim 8, wherein the hydrophilicity-hydrophobicity matching layer is a silicon oxide layer, a silicon nitride layer, or a composite layer of silicon oxide and silicon nitride.

10. The array substrate according to claim 7, wherein the hydrophilicity-hydrophobicity matching layer is disposed on the organic filling layer and covers the sources and the drains.

11. The array substrate according to claim 7, further comprising a planarization layer disposed on the hydrophilicity-hydrophobicity matching layer and covering the sources and the drains.

12. The array substrate according to claim 10, further comprising a second gate insulating layer disposed between the first gate insulating layer and the intermediate dielectric layer, and a second gate disposed between the second gate insulating layer and the intermediate dielectric layer.

13. The array substrate according to claim 11, further comprising a second gate insulating layer disposed between the first gate insulating layer and the intermediate dielectric layer, and a second gate disposed between the second gate insulating layer and the intermediate dielectric layer.

14. A display panel, comprising:
an array substrate comprising a flexible substrate, a buffer layer, a semiconductor layer, a first gate insulating layer, a first gate, an intermediate dielectric layer, an organic filling layer, a plurality of sources, and a plurality of drains sequentially disposed;
a first electrode layer disposed on the array substrate;
a pixel definition layer disposed on the array substrate and partially covering the first electrode layer;
a luminous layer disposed on the first electrode layer; and
a second electrode layer disposed on the luminous layer,
wherein the display panel further comprises:
a hydrophilicity-hydrophobicity matching layer disposed among the organic filling layer, the sources, and the drains.

15. The display panel according to claim 14, further comprising a planarization layer disposed on the hydrophilicity-hydrophobicity matching layer and covering the sources and the drains.

16. The display panel according to claim 14, wherein the hydrophilicity-hydrophobicity matching layer consists of an inorganic material.

17. The display panel according to claim 16, wherein the hydrophilicity-hydrophobicity matching layer is a silicon oxide layer, a silicon nitride layer, or a composite layer of silicon oxide and silicon nitride.

18. The display panel according to claim 14, wherein the hydrophilicity-hydrophobicity matching layer is disposed among the organic filling layer, the first electrode layer, and part of the pixel definition layer.

19. The display panel according to claim 15, wherein the array substrate further comprises a second gate insulating layer disposed between the first gate insulating layer and the intermediate dielectric layer, and a second gate disposed between the second gate insulating layer and the intermediate dielectric layer.

20. The display panel according to claim 18, wherein the array substrate further comprises a second gate insulating layer disposed between the first gate insulating layer and the intermediate dielectric layer, and a second gate disposed between the second gate insulating layer and the intermediate dielectric layer.
